(19) United States
(12) Patent Application Publication
(10) Pub. No.: US 2026/0190432 A1
(43) Pub. Date: Jul. 2, 2026

(54) METHOD FOR PREVENTING VOIDS IN CONTACT PLUGS USING SELECTIVE PASSIVATION LAYERS IN SEMICONDUCTOR FABRICATION

(71) Applicant: TAIWAN SEMICONDUCTOR MANUFACTURING COMPANY, LTD., Hsinchu (TW)

(72) Inventors: Man-Nung SU, Taipei City (TW); Shih-Jung HO, Hsinchu City (TW); Po-Chin CHANG, Taichung City (TW); Peng-Hsuan CHIANG, Hsinchu City (TW); Ku-Feng YANG, Hsinchu County (TW); Sung-Li WANG, Hsinchu County (TW); Szuya LIAO, Hsinchu County (TW); Pinyen LIN, Rochester, NY (US)

(73) Assignee: TAIWAN SEMICONDUCTOR MANUFACTURING COMPANY, LTD., Hsinchu (TW)

(21) Appl. No.: 19/008,509

(22) Filed: Jan. 2, 2025

(51) Int. Cl. H10D 64/66; H01L 21/768; H10D 30/00; H10D 30/01; H10D 30/43; H10D 62/10; H10D 62/13; H10D 84/01; H10D 84/85

(52) U.S. Cl. CPC H10D 64/668; H10D 30/014; H10D 30/0191; H10D 30/43; H10D 30/502; H10D 62/121; H10D 62/151; H10D 84/017; H10D 84/0186; H10D 84/851; H10W 20/033; H10W 20/042

(57) ABSTRACT

This disclosure provides a method to prevent void formation in contact plugs during semiconductor device fabrication by selectively forming passivation layers on metal-containing materials. Specifically, passivation layers can be deposited on metal-rich regions, while avoiding deposition on non-metal materials. By selectively passivating the metal surfaces, the subsequent deposition of a metal-containing layer occurs only on the dielectric materials. After the seed layer is deposited, the passivation layers are removed to expose the metal surfaces. This can prevent the conductive material from accumulating too quickly on the metal surfaces during contact plug formation. As a result, the contact plug can fill the openings uniformly, effectively preventing the formation of voids that could hinder electrical connectivity.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of a semiconductor structure in accordance with some embodiments of the present disclosure.

FIGS. 2A-14B illustrate schematic cross-sectional views of intermediate stages in the formation of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

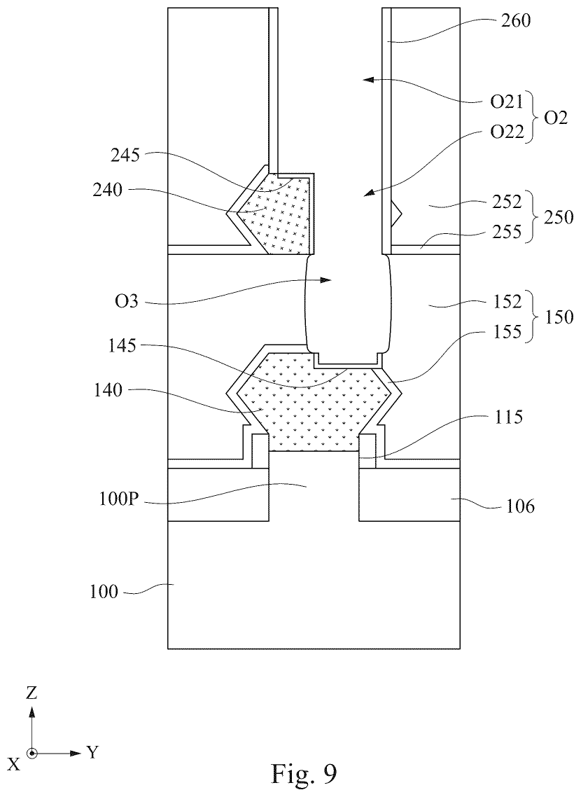

In semiconductor device fabrication, forming reliable contact plugs can ensure proper electrical connectivity between components. An issue may arise due to uneven deposition rates of conductive materials on metal-containing surfaces compared to dielectric materials. Metal surfaces, such as silicide layers, facilitate rapid accumulation of conductive material, which can prematurely seal openings (e.g., opening O2 as shown in FIG. 9) before deeper regions (e.g., opening O3 as shown in FIG. 9) are adequately filled. This results in voids within the contact plugs, leading to increased electrical resistance or open circuits. Such voids compromise device performance and reliability.

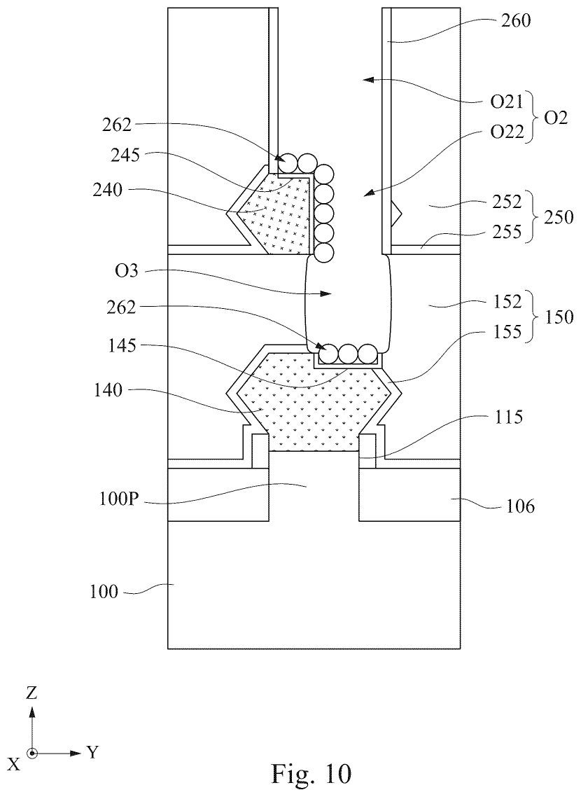

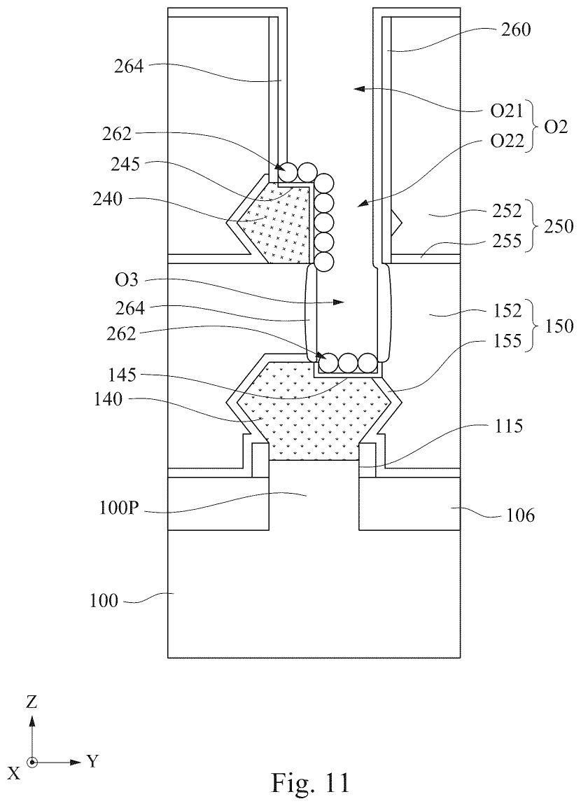

Therefore, the present disclosure in various embodiments provides a method to prevent void formation in contact plugs during semiconductor device fabrication by selectively forming passivation layers on metal-containing materials. Specifically, passivation layers (e.g., passivation layers 262 shown in FIG. 10) can be deposited on metal-rich regions (e.g., first and second silicide layers 145 and 245 shown in FIG. 10), while avoiding deposition on non-metal materials (e.g., spacer layer 260 and isolation structures 150 and 250 shown in FIG. 10). By selectively passivating the metal surfaces, the subsequent deposition of a metal-containing layer (e.g., seed layer 264 shown in FIG. 11) occurs only on the dielectric materials. After the seed layer is deposited, the passivation layers are removed to expose the metal surfaces. This can prevent the conductive material from accumulating too quickly on the metal surfaces during contact plug formation. As a result, the contact plug can fill the openings uniformly, effectively preventing the formation of voids that could hinder electrical connectivity. Therefore, this method can enhances the reliability and performance of semiconductor devices by ensuring void-free contact plugs and robust electrical connections between metal-containing regions.

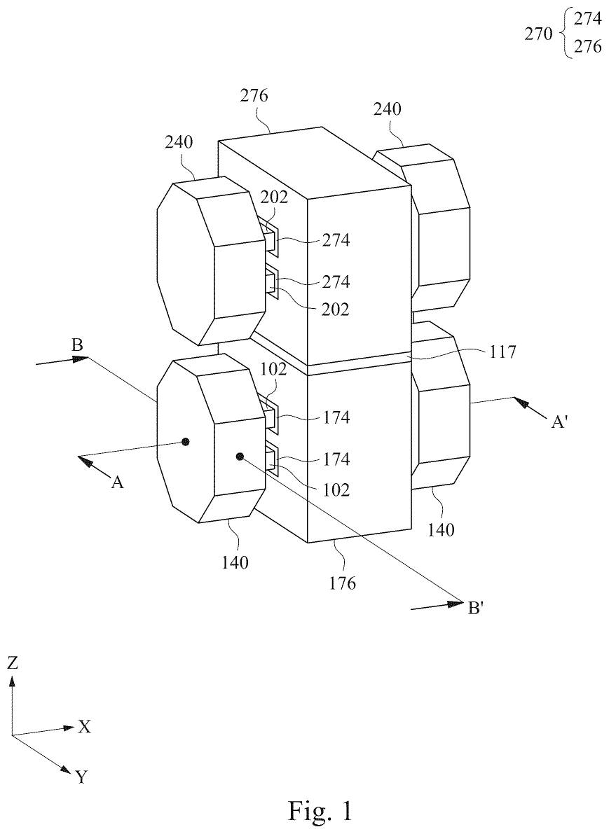

Reference is made to FIG. 1. FIG. 1 illustrates an example of a CFET schematic, in accordance with some embodiments. FIG. 1 is a three-dimensional view, where some features of the CFETs are omitted for illustration clarity. Cross-section A-A′ in FIG. 1 is parallel to a longitudinal axis of the semiconductor nanostructures 102/202 of a CFET and in a direction of, for example, a current flow between the source/drain regions 140/240 of the CFET. Cross-section B-B′ in FIG. 1 is parallel to a longitudinal axis of the metal gate structure 170/270 of the CFET. Subsequent figures refer to these reference cross-sections for clarity. Subsequent figures refer to these reference cross-sections for clarity.

In some embodiments, the CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures (including lower semiconductor nanostructures 102 and upper semiconductor nanostructures 202), where the semiconductor nanostructures 102 and 202 act as channel regions for the nanostructure-FETs. The semiconductor nanostructures 102 and 202 may be nanosheets, nanowires, or the like. The lower semiconductor nanostructures 102 are for a lower nanostructure-FET and the upper semiconductor nanostructures 202 are for an upper nanostructure-FET. A channel isolation material (e.g., isolation layer 117) may be used to separate and electrically isolate the upper semiconductor nanostructures 202 from the lower semiconductor nanostructures 102.

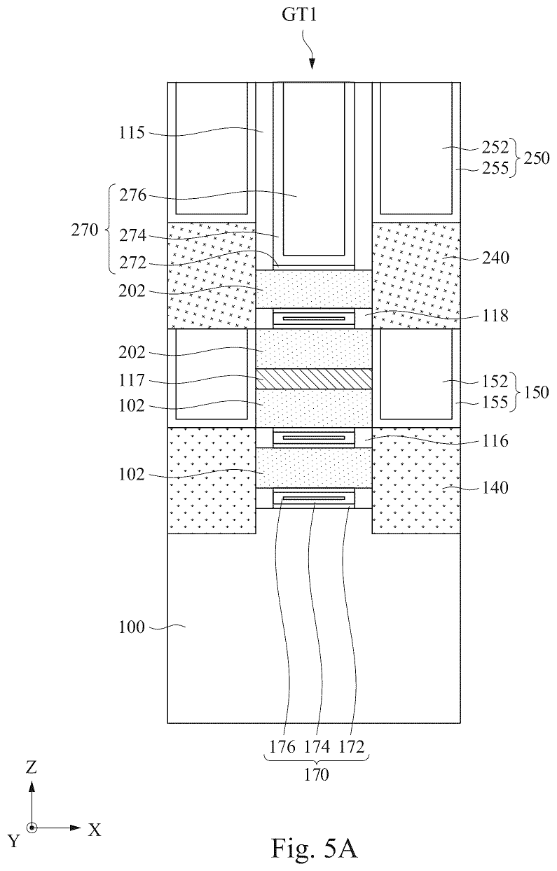

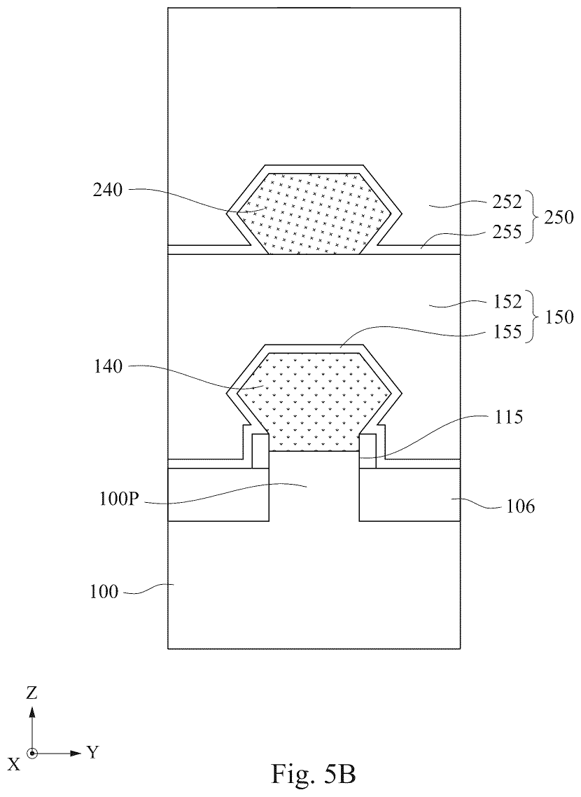

Gate dielectric layers 174 and 274 are along top surfaces, sidewalls, and bottom surfaces of the semiconductor nanostructures 102 and 202. Gate electrodes (including a lower gate electrode layer 176 and an upper gate electrode layer 276) are over the gate dielectric layers 174 and 274 and around the semiconductor nanostructures 102 and 202. Source/drain regions (including lower epitaxial source/drain regions 140 and upper epitaxial source/drain regions 240) are disposed at opposing sides of the gate dielectric layers 174 and the gate dielectric layers 274. The epitaxial source/drain region 140/240 may refer to a source or a drain, individually or collectively dependent upon the context. Isolation features (e.g., isolation structure 150 114 as shown in FIGS. 5A and 5B) may be formed to separate desired ones of the epitaxial source/drain region 140 and 240. For example, a lower gate electrode layer 176 may optionally be separated from an upper gate electrode layer 276 by an isolation layer 117. Alternatively, a lower gate electrode layer 176 may be coupled to an upper gate electrode layer 276. Further, the upper epitaxial source/drain regions 240 may be separated from lower epitaxial source/drain regions 140 by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

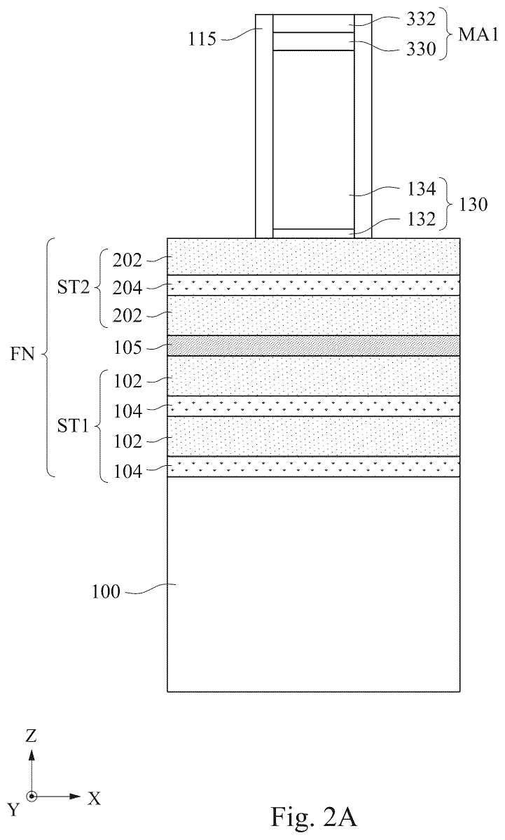

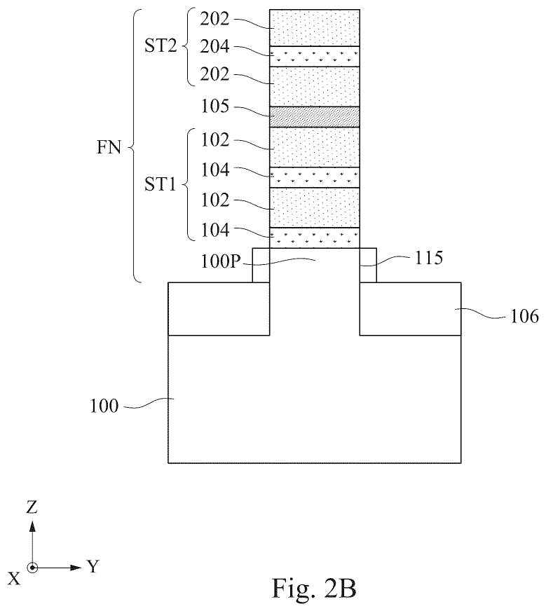

Reference is made to FIGS. 2A-14B. FIGS. 2A-14B illustrate schematic cross-sectional views of intermediate stages in the formation of a semiconductor structure in accordance with some embodiments of the present disclosure. FIGS. 2A, 3A, 4A, and 5A illustrate cross-sectional views obtained from reference cross-sections A-A′ in FIG. 1, and FIGS. 2B, 3B, 4B, 5B, and 6-14B illustrate cross-sectional views obtained from reference cross-sections B-B′ in FIG. 1. It is understood that additional operations can be provided before, during, and after the processes shown by FIGS. 2A-14B, and some of the operations described below can be replaced or eliminated, for additional embodiments of the method. The order of the operations/processes may be interchangeable.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A fin structure FN is formed over the substrate 100. The fin structure FN includes a semiconductor strip 100P, a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

After the fin structure FN is formed, isolation structures 106 are formed over the substrate 100 and laterally surrounding the fin structure FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

Subsequently, a dummy gate structure 130 is formed over the substrate 100 and crossing the fin structure FN. In some embodiments, the dummy gate structure 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming a patterned mask MA1 over the dummy gate layer, and then performing an etching process to the dummy dielectric layer and the dummy gate layer by using the patterned mask MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, the patterned mask MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of the dummy gate structure 130 and on opposite sidewalls of the fin structure FN. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structure 130 and on sidewalls of the fin structure FN. In some embodiments, portions of the spacers 115 on sidewalls of the dummy gate structures 130 can be referred to as gate spacers, and the portions of the spacers 115 on sidewalls of the fin structure FN can be referred to as fin spacers. In some embodiments, the spacer layer may be deposited using techniques such CVD, ALD, or the like.

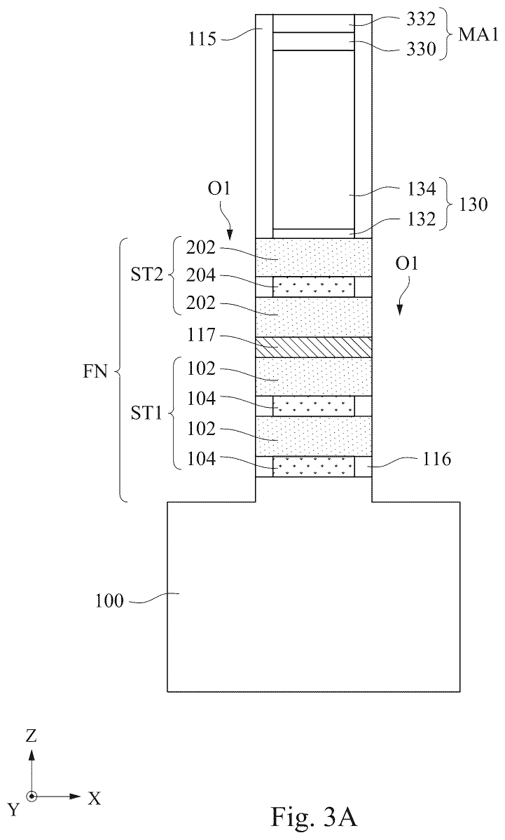

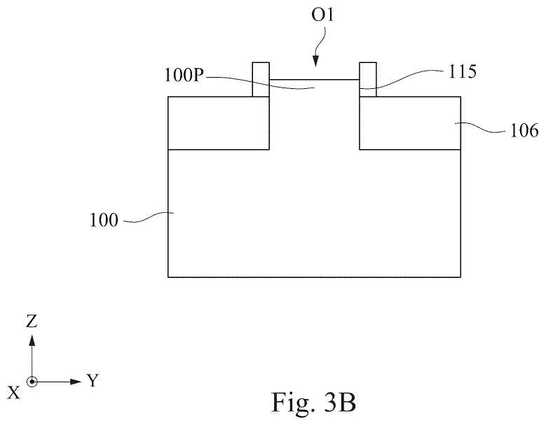

Reference is made to FIGS. 3A and 3B. An etching process is performed to remove portions of the fin structure FN by using the dummy gate structure 130 and the gate spacers 115 as etch mask, so as to form source/drain openings O1 in the fin structure FN. In some embodiments, the etching process may be wet etch, dry etch, or combinations thereof.

After the source/drain openings O1 are formed, inner spacers 116 are formed on opposite ends of each of the semiconductor layers 104 and 204, and the semiconductor layer 105 is replaced with an isolation layer 117. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

The inner spacers 116 and the isolation layer 117 can be formed by, for example, performing an etching process to laterally etch the semiconductor layers 104 and 204 to form sidewall recesses, and to remove the semiconductor layer 105 to form a gap. In some embodiments, the sidewalls of the semiconductor layers 104, 105, and 204 may be etched using isotropic etching processes, such as wet etching or the like. In some embodiments where the semiconductor layers 104, 105, and 204 include, e.g., SiGe, and the semiconductor layers 102 and 202 include, e.g., Si, an etch process with tetramethylammonium hydroxide (TMAH), ammonium hydroxide (NH₄OH), or the like may be used to etch sidewalls of the semiconductor layers 104, 105, and 204. In some embodiments, because the semiconductor layer 105 may include different germanium concentration than the semiconductor layers 104 and 204, the etchant of the etching process may be selected such that the etching process includes a higher etch rate to the semiconductor layer 105 than to the semiconductor layers 104 and 204. As a result, the semiconductor layer 105 can be removed, while the semiconductor layers 104 and 204 are slightly etched to form the sidewall recesses. Then, inner spacers 116 are formed in the sidewall recesses on opposite ends of each of the semiconductor layers 104 and 204, and the isolation layer 117 is formed in the gap. In some embodiments, the inner spacers 116 and the isolation layer 117 may be formed by, for example, depositing a dielectric material blanket over the substrate 100 and filling the sidewall recesses and the gap, and then performing an anisotropic etching to remove portions of the dielectric material outside the sidewall recesses and the gap, leaving the remaining portions of the dielectric material in the sidewall recesses and the gap as the inner spacers 116 and the isolation layer 117, respectively.

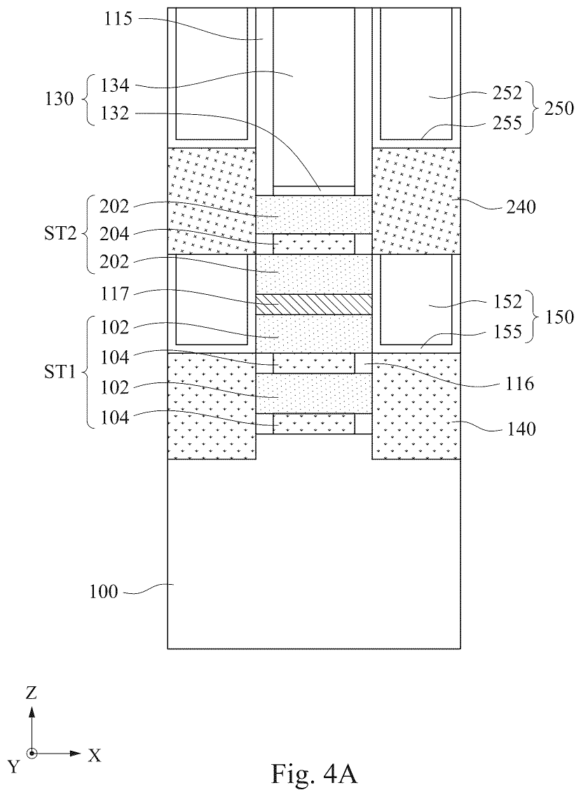

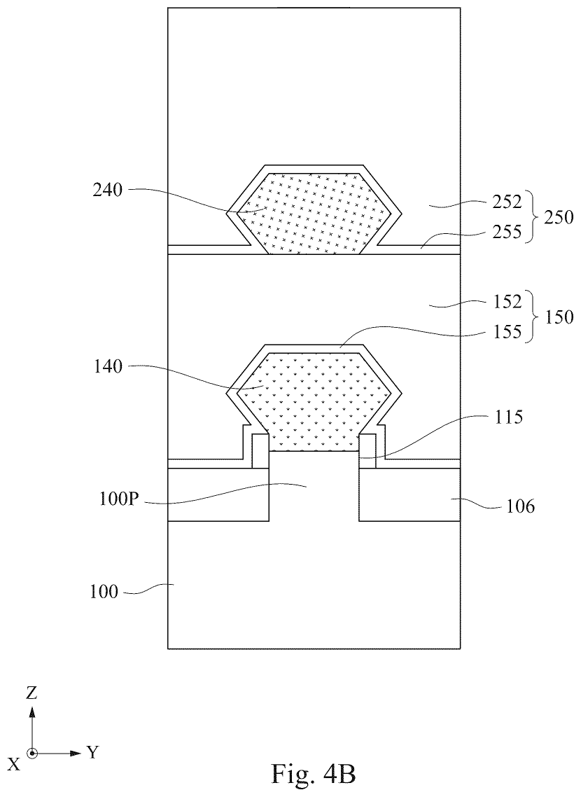

Reference is made to FIGS. 4A and 4B. First epitaxial source/drain regions 140 are formed on opposite ends of the exposed semiconductor layer 102. In some embodiments, the first epitaxial source/drain regions 140 may include semiconductor material, such as silicon germanium (SiGe), or other suitable semiconductor material. In some embodiments, the first epitaxial source/drain regions 140 may be formed by a selective epitaxial growth (SEG) process. The SEG process may selectively grow a semiconductor material on exposed semiconductor surfaces, such as the exposed surfaces of the semiconductor layer 102. In some embodiments, during forming the first epitaxial source/drain regions 140, a protective layer may be formed covering the semiconductor layers 202, such that the SEG process would not grow a semiconductor material from surfaces of the semiconductor layers 202. In some embodiments, the first epitaxial source/drain regions 140 may be doped with p-type dopants, such as boron (B), gallium (Ga), indium (In), aluminium (Al), or the like. In other embodiments, the first epitaxial source/drain regions 140 may be doped with n-type dopants, such as n-type dopants, such as phosphorus (P), arsenic (As), or antimony (Sb), or the like.

A contact etch stop layer (CESL) 155 is formed covering the first epitaxial source/drain regions 140. Afterwards, an interlayer dielectric (ILD) layer 152 is formed over the CESL 155. Then, an etching back process is performed to lower top surfaces of the CESL 155 and the ILD layer 152 to a position, such that at least the topmost one of the semiconductor layers 202 are exposed through the source/drain openings O1. In some embodiments, the CESL 155 and the ILD layer 152 can be collectively referred to as an isolation structure 150. In some embodiments, the topmost one of the semiconductor layers 102 and the bottommost one of the semiconductor layers 202 may be covered by the isolation structure 150.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide. The CESL 155 and the ILD layer 152 can be formed using, for example, CVD, ALD or other suitable techniques.

Second epitaxial source/drain regions 240 are formed on opposite ends of the exposed semiconductor layer 202. In some embodiments, the second epitaxial source/drain regions 240 may be formed by a selective epitaxial growth (SEG) process. The SEG process may selectively grow a semiconductor material on exposed semiconductor surfaces, such as the exposed surfaces of the exposed semiconductor layer 202. In some embodiments, the second epitaxial source/drain regions 240 may be doped with n-type dopants, such as phosphorus (P), arsenic (As), or antimony (Sb), or the like.

A contact etch stop layer (CESL) 255 is formed covering the second epitaxial source/drain regions 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structure 130 is exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively, and thus relevant details will not be repeated for brevity.

Reference is made to FIGS. 5A and 5B. The dummy gate structure 130 is removed to form gate trench GT1 between the gate spacers 115. Then, an etching process is performed to remove the semiconductor layers 104 and 204, such that at least the topmost one of the semiconductor layers 202 and at least the bottommost one of the semiconductor layers 102 are suspended over the substrate 100.

Subsequently, interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 and 276 are formed in the gate trench GT1 and over the gate dielectric layers 174 and 274, respectively. In some embodiments, the gate electrodes 176 and 276 may include a same material or different materials. In the embodiments where the gate electrodes 176 and 276 are made of different materials, the gate electrode 176 is formed in the gate trench GT1, the gate electrode 176 is then etched back, such that the remaining gate electrode 176 is at the lower portion of the gate trench GT1. Afterwards, the gate electrode 276 is then formed in the upper portion of the gate trench GT1 and over the gate dielectric layers 274.

Accordingly, first metal gate structure 170 and second metal gate structure 270 are formed. In greater detail, the first metal gate structure 170 is formed in bottom portion of the gate trench GT1, such that the first metal gate structure 170 may wrap around the respective semiconductor layer 102. The second metal gate structure 270 is formed in upper portion of the gate trench GT1 and above the first metal gate structure 170, such that the second metal gate structure 270 may wrap around the respective semiconductor layer 202. In some embodiments, the first metal gate structure 170 may include the interfacial layer 172, the gate dielectric layer 174 over the interfacial layer 172, and the gate electrode 176 over the gate dielectric layer 174. The second metal gate structure 270 may include the interfacial layer 272, the gate dielectric layer 274 over the interfacial layer 272, and the gate electrode 276 over the gate dielectric layer 274.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 and 276 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

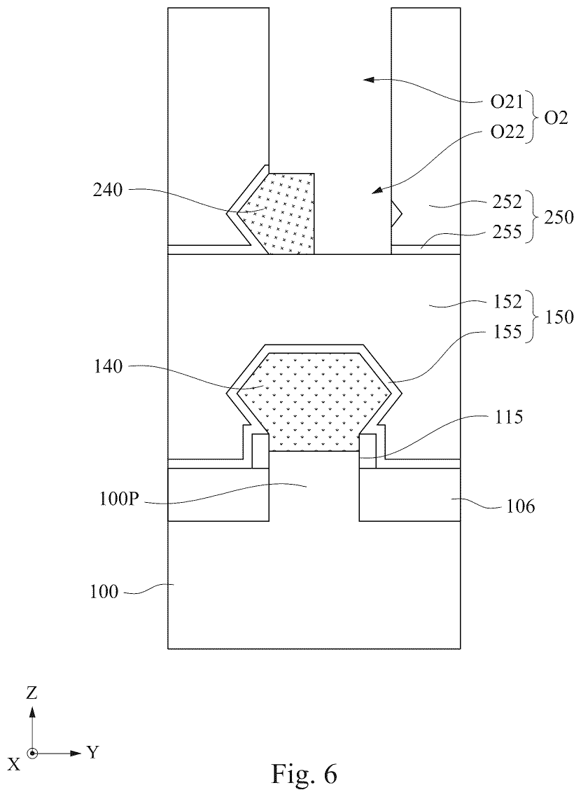

Reference is made to FIG. 6. The isolation structure 250 is patterned to form an opening O2 in the isolation structure 250. In some embodiments, the opening O2 can expose the underlying isolation structure 150. In greater detail, portions of the ILD layer 252 and the CESL 255 are removed during the patterning process, such that top surface of the second epitaxial source/drain region 240 is exposed through the opening O2. In some embodiments, the isolation structure 250 can be patterned, for example, forming a mask layer (not shown) over the substrate 100 and exposing unwanted portion of the isolation structure 250, performing an etching process to remove the unwanted portion of the isolation structure 250 until top surface the second epitaxial source/drain region 240 is exposed, and then removing the mask layer once the etching process is complete. In some embodiments, a portion of the second epitaxial source/drain region 240 may also be removed during the etching process. In some embodiments, the etching process may include an anisotropic etching process, such as a plasma dry etch.

In some embodiments, the opening O2 can be formed using a two-stage etching process. The first stage can include applying a patterned first mask layer over the isolation structure 250. This initial etching step can create the upper portion of opening O2, exposing the top surface of the second epitaxial source/drain region 240. The patterned first mask can ensure that the etching can be selective, targeting only the designated areas, which in turn results in a well-defined upper section of the opening O2. Next, a second mask layer is patterned over at least part of the upper portion of the opening O2. This second stage of etching can form the lower portion of the opening O2. The lower etching stage can extend deeper, penetrating through the second epitaxial source/drain region 240 and ultimately exposing the isolation structure 150 beneath it. Consequently, the lower portion of opening O2 can be narrower than the upper portion of the opening O2, creating a stepped profile. Once the two-stage etching is complete, both the first and second mask layers can be removed, leaving the structure of opening O2 with its distinct upper and lower sections.

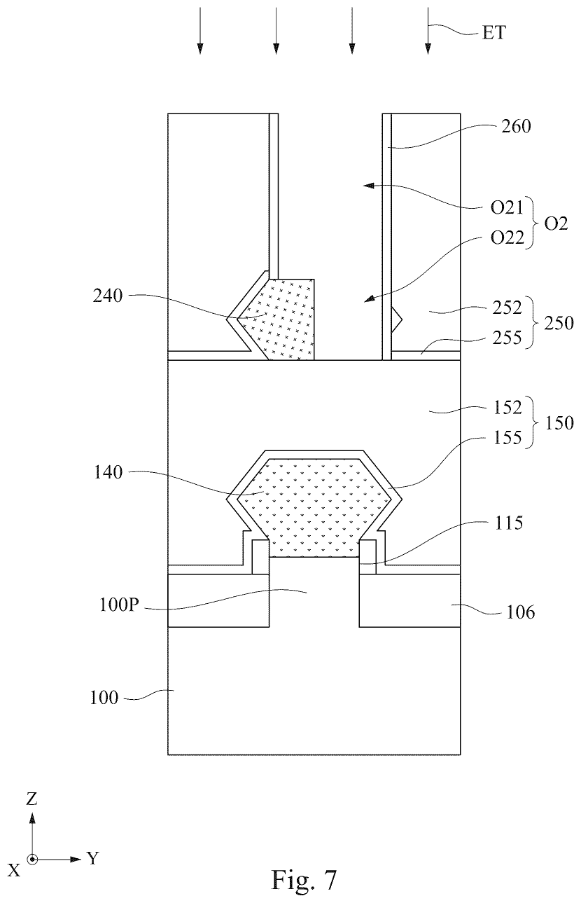

Reference is made to FIG. 7. A spacer layer 260 can be deposited over the substrate 100 and line the opening O2 in the isolation structure 250. In greater detail, the spacer layer 260 may line the opposite sidewalls and bottom of the opening O2. In some embodiments, the spacer layer 260 may be made of a dielectric material, such as silicon nitride (SiN), silicon oxynitride (SiON), and other carbon-doped low-k dielectrics, such as SiOCN material. The spacer layer 260 may be formed using suitable deposition process, such as physical vapor deposition (PVD), chemical vapor deposition (CVD), atomic layer deposition (ALD), or other suitable deposition process.

Subsequently, an etching process ET is performed to remove portions of the spacer layer 260. In some embodiments, the etching process ET may be a directional etching process, such as a plasma dry etching, in which the etchants (e.g., particles, ions, plasma) may be directed along a certain direction (e.g., the vertical direction). Accordingly, the etching process ET may substantially remove the horizontal portions of the spacer layers 260, while leaving the vertical portions of the spacer layer 260 remaining over the substrate 100 once the etching process ET is complete. As illustrated in FIG. 7, the spacer layer 260 near the bottom of opening O2 can be also removed during the etching process, meaning that the spacer layer 260 on the second epitaxial source/drain region 240 is eliminated, which in turn allows for better exposure of the source/drain region in subsequent processing.

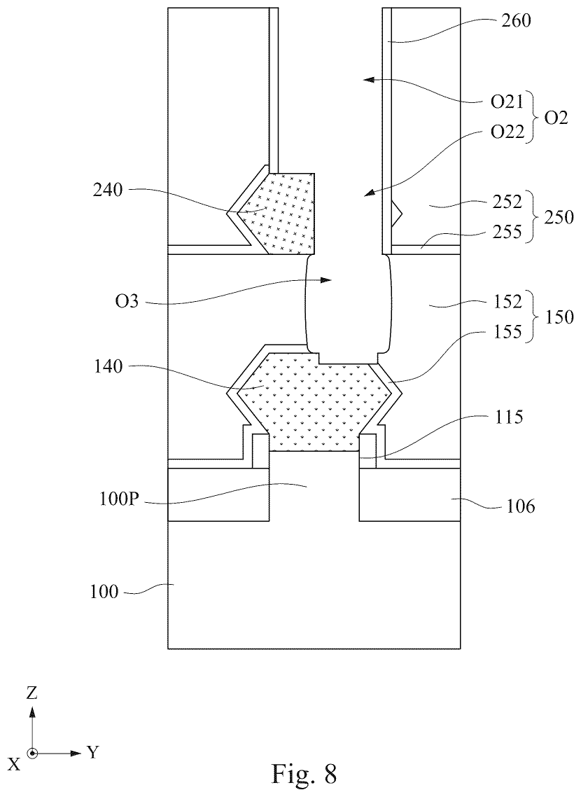

Reference is made to FIG. 8. The isolation structure 150 is patterned to form an opening O3 in the isolation structure 150 to expose the first epitaxial source/drain region 240, and the opening O3 can be spatially connected with the opening O2. In greater detail, portions of the ILD layer 152 and the CESL 155 are removed during the patterning process, such that top surface of the second epitaxial source/drain region 240 is exposed from the opening O3. In some embodiments, a portion of the second epitaxial source/drain region 140 may also be removed during the etching process, such that a recessed portion can be formed on the top surface of the second epitaxial source/drain region 140. In some embodiments, the etching process may include an anisotropic etching process, such as a plasma dry etch.

In some embodiments, when etching the isolation structure 150, the ILD layer 152 can undergoe not only vertical etching but also slight lateral etching. Consequently, the resulting opening O3 formed by this etching process can has a profile that is wider in the middle and narrower at the top and bottom. This profile can be a result of the lateral etching component, which causes the middle section of the opening to expand slightly more than the rest. As shown in FIG. 8, the width of opening O3 can be greater than the width of the lower portion of opening O2, and part of opening O3 can extend beneath the second epitaxial source/drain region 240. In some embodiments, patterning the opening O3 can be performed such that a lateral dimension of the opening O3 below the second epitaxial source/drain region 240 can be greater than a lateral dimension of the opening O3 in the same level as the second epitaxial source/drain region 240.

Reference is made to FIG. 9. A first silicide layer 145 and a second silicide layer 245 are formed on the first epitaxial source/drain region 140 and the second epitaxial source/drain region 240, respectively. In greater detail, the first silicide layer 145 and the second silicide layer 245 are formed selectively on the exposed surfaces of the first epitaxial source/drain region 140 and the second epitaxial source/drain region 240. For example, the first silicide layer 145 and the second silicide layer 245 may be formed by, for example, depositing a metal layer into the openings O2 and O3, and then performing an annealing process so that portions of the metal layer may react with the first epitaxial source/drain region 140 and the second epitaxial source/drain region 240 to form the first silicide layer 145 and the second silicide layer 245. In some embodiments, the un-reacted portions of the metal layer may then be removed using suitable etching process. In some embodiments, the first silicide layer 145 and the second silicide layer 245 may include titanium silicide (TiSi), titanium disilicide (TiSi₂), molybdenum silicide (MoSi₂), tungsten silicide (WSi₂), tantalum silicide (TaSi₂), or other suitable silicide. In some embodiments, a footprint of the opening O3 between the first and second epitaxial source/drain regions 140 and 240 can overlap with footprints of the first and second metal silicide layers 145 and 245 on the substrate 100.

Reference is made to FIG. 10. After constructing the semiconductor structure illustrated in FIG. 9, passivation layers 262 can be formed over metal-rich areas, such as the first silicide layers 145 and the second silicide layer 245. This process involves the selective formation of passivation layers 262 on metal-containing materials while avoiding deposition on non-metal materials such as dielectric layers, such as the spacer layer 260 and the isolation structures 150 and 250. The selective formation of the passivation layers 262 can be achieved through the use of materials and processes that exploit the inherent chemical differences between metal-containing and dielectric materials. The passivation layers 262 can function as inhibitors or self-assembled monolayers (SAMs), serving to protect the metal surfaces from unwanted reactions during subsequent fabrication steps. In some embodiments, the passivation layer 262 can be interchangeable referred to as an inhibitor layer or an inhibitor.

In some embodiments, the passivation layers 262 can be composed of various materials, including polymers and hydrocarbons. In some embodiments, the passivation layers 262 can be made of a carbon-containing material. In some embodiments, the passivation layers 262 can be made of hydrocarbons that possess resonant electrons—molecules such as dienes, aromatic rings, pyridine, pyrrole, aniline, benzotriazole (BTA), or combinations thereof. These hydrocarbons can have resonant electrons can interact with the metal surfaces, forming coordination bonds or engaging in π-electron interactions. This selective adhesion can occur because the electronic structures of these hydrocarbons have a natural affinity for the d-orbitals of metal atoms present in the silicide layers (e.g., first silicide layers 145 and second silicide layer 245). For instance, the delocalized electrons in aromatic rings or conjugated systems can overlap with the d-orbitals of metal atoms, forming stable complexes. When the semiconductor structure is placed in a deposition chamber, vaporized or liquid hydrocarbons with resonant electrons can be introduced along with reaction gases. The molecular properties of these hydrocarbons can cause them to preferentially adhere to metal surfaces, such as the first and second silicide layers 145 and 245, rather than to dielectric materials (e.g., spacer layer 260 and isolation structures 150 and 250.). This selective adhesion can be due to the lack of suitable electronic structures in dielectric materials to interact with the resonant electrons of the hydrocarbons.

In some embodiments, the passivation layers 262 are formed using silane-type or thiol-type passivation agents. These molecules can have distinct structural features that facilitate selective bonding with specific surface terminations. Silane-type passivation agents, for example, possess a first protruding end portion, known as the head group, which can selectively attach to hydroxyl group-terminated surfaces, such as silicon oxide surfaces. The second protruding end portion, or terminal group, acts as a metal oxide deposition inhibitor. Between these two ends, there may be an optional middle portion consisting of an alkyl chain, which promotes ordered self-assembly through Van der Waals interactions. When silane-type passivation agents are used, they form covalent bonds with hydroxyl-terminated surfaces via their reactive head groups. This process can effective on metal surfaces that have been naturally oxidized to form a thin layer of metal oxide terminated with hydroxyl groups. The silicon atom in the head group forms a strong Si—O—Si linkage with the surface hydroxyl groups. The dielectric materials, which may have hydrogen-terminated surfaces, after treatments like NH₄F to remove native oxides, do not react with these silane compounds, thereby ensuring selective passivation. For forming the silane-type passivation layer, the process may involve cleaning the metal surfaces to ensure the presence of hydroxyl terminations, followed by exposure to silane vapors. The reactive head groups of the silane molecules can bond with the surface hydroxyl groups, forming a self-assembled monolayer.

Thiol-type passivation agents can operate on a similar principle but utilize the strong affinity between thiol groups (—SH) and metal surfaces, forming metal-sulfur bonds upon contact. The thiol head group binds specifically to metal atoms, while the alkyl chain and terminal group can be modified to adjust the properties of the passivation layer. In some embodiments, this chemisorption process may result in a densely packed monolayer on the metal surface. Alkanethiols, such as propanethiol, butanethiol, hexanethiol, octadecanethiol, nonanethiol, or dodecanethiol, have a thiol head group that forms a robust metal-sulfur bond with the metal surfaces. The alkyl chains can facilitate the formation of an ordered monolayer, and the terminal groups can be tailored to provide specific surface properties. For forming the tshiol-type passivation layer, the process may involve immersing the structure in a solution containing the thiol molecules or introducing them in vapor form. The thiol groups can bond with the metal surfaces, and the alkyl chains can align to form an ordered layer. In some embodiments, this process can be self-limiting, as the formation of the monolayer may inhibit further adsorption once complete coverage is achieved.

Reference is made to FIG. 11. After the formation of passivation layers 262 over the metal-containing regions (first silicide layers 145 and second silicide layer 245), a deposition process such as chemical vapor deposition (CVD) or atomic layer deposition (ALD) is employed to form a metal-containing seed layer 264. The seed layer 264 can be intended to deposit only on the dielectric materials, such as the spacer layer 260 and the isolation structures 150 and 250, while leaving the passivated metal surfaces untouched. In some embodiments, the seed layer 264 can be made of a conductive material that include one or more layers of Co, Ni, W, Ru, Ti, Ta, Cu, Al, TiN, and TaN, combinations thereof, and/or other suitable material. In some embodiments, the metal-containing seed layer 264 can be interchangeable referred to as a metal liner.

The selective formation of the metal-containing seed layer 264 on dielectric materials and not on the passivation layers 262 can be due to the differences in surface chemistry and physical properties between these materials. The passivation layers 262 formed over the metal-containing regions (e.g., first silicide layers 145 and second silicide layer 245) can composed of organic molecules such as polymers, hydrocarbons with resonant electrons, silane-type agents, or thiol-type agents, creating a surface that is chemically inert and has low surface energy. These organic passivation layers can be hydrophobic, meaning they repel polar molecules and do not readily interact with deposition precursors, which are often polar or metallic in nature. In some embodimetns, the passivation layers 262 can eliminate or block reactive sites on the metal surface, preventing adsorption or nucleation of additional materials. In other words, the formation of the seed layer 264 may require overcoming an energy barrier associated with nucleation. Due to the unfavorable interactions and lack of adhesion, the energy barrier for nucleation on the passivation layers 262 may be high. Therefore, the passivation layers 262 can act as barriers, physically and chemically blocking the deposition precursors from reaching the underlying metal surfaces.

On the other hand, dielectric materials (e.g., spacer layer 260 and isolation structures 150 and 250) can have surfaces terminated with reactive groups such as hydroxyl (—OH) groups, after certain cleaning or preparation steps. The dielectric surfaces of the spacer layer 260 and isolation structures 150 and 250 can be hydrophilic, promoting interactions with polar molecules and deposition precursors. The presence of surface hydroxyl groups or other reactive sites can facilitates the adsorption and nucleation of the metal-containing seed layer. In other words, the dielectric surfaces can offer favorable interactions that lower the nucleation energy barrier, facilitating seed layer formation. Therefore, the precursors may react with hydroxyl or other reactive groups on the dielectric surfaces but have little to no reaction with the inert, passivated metal surfaces.

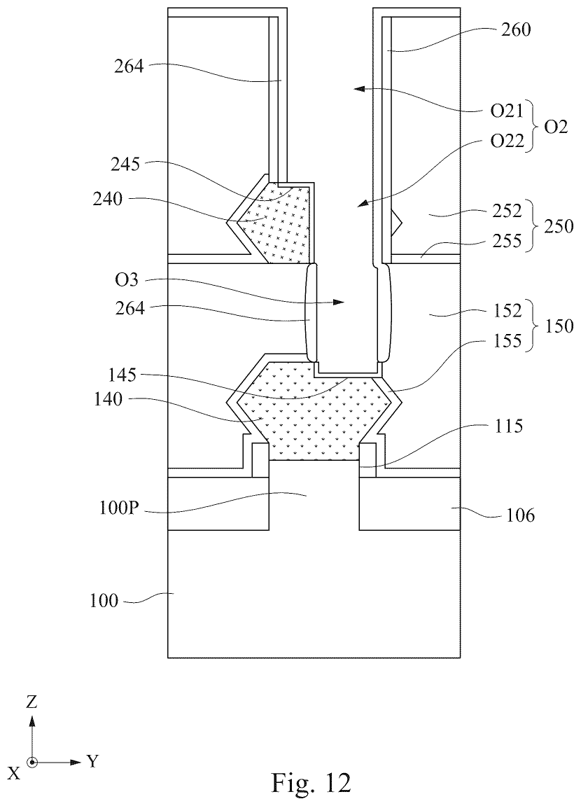

Reference is made to FIG. 12. After forming the seed layer 264, the passivation layers 262 (referring to FIG. 11) over the metal-containing regions such as the first silicide layers 145 and the second silicide layer 245 are removed to expose the underlying metal surfaces for subsequent processing steps. The removal of the passivation layers 262 can be controlled to prevent damage to the underlying metal-containing regions and to ensure that the surfaces are properly prepared for subsequent fabrication steps.

In some embodiments where the passivation layer 262 is composed of hydrocarbons with resonant electrons or is a thiol-type passivation, the removal process can include breaking the bonds between the passivation molecules and the metal-containing materials. This is achieved by applying elevated temperatures, in the range of about 250 to 450° C., such as about 250, 300, 350, 400, or 450° C. The temperatures used can be enough to break the chemical bonds but are within a range that does not adversely affect the metal silicide layers or other components of the semiconductor device.

The hydrocarbons with resonant electrons can adhere to the metal surfaces through coordination bonds or π-electron interactions. These interactions can involve the overlap of delocalized electrons in the aromatic rings or conjugated systems of the hydrocarbons with the d-orbitals of the metal atoms in the silicide layers. Similarly, thiol-type passivation agents form strong metal-sulfur bonds with the metal surfaces due to the high affinity between the thiol groups (—SH) and the metal atoms. When the semiconductor structure is subjected to elevated temperatures within the specified range, the thermal energy provided can be sufficient to disrupt these bonds. The coordination bonds and π-electron interactions in the hydrocarbons with resonant electrons may become unstable as the electrons gain kinetic energy, leading to the detachment of the passivation molecules from the metal surfaces. In the case of thiol-type passivation, the metal-sulfur bonds may absorb the thermal energy and break apart, causing the thiol molecules to release from the metal surfaces. As a result, the passivation layers 262 can be effectively removed, exposing the underlying metal-containing regions.

After the thermal treatment, any residual passivation material may be eliminated through cleaning processes. The decomposed passivation molecules or fragments can be washed away using dilute acidic solutions such as phosphoric acid (H₃PO₄) or hydrochloric acid (HCl). These solutions can help to dissolve remaining organic residues without damaging the metal silicide layers or other components of the semiconductor structure.

In some embodiments where the passivation layer 262 is composed of silane-type passivation agents, the removal process can include the application of elevated temperatures in the range of about 250 to 450° C., such as about 250, 300, 350, 400, or 450° C. Silane-type passivation layers can be formed through covalent bonds between the silicon atoms in the head groups of the silane molecules and the hydroxyl-terminated surfaces of the metal oxides, resulting in strong Si—O—Si linkages. The passivation layer includes an organic component, often an alkyl chain, which contains carbon-hydrogen (C—H) bonds. When the structure is heated to the specified temperatures, the thermal energy induces the decomposition of the C—H bonds within the alkyl chains of the silane molecules. The breaking of these bonds can leads to the degradation of the organic component of the passivation layer 262. As the alkyl chains decompose, the integrity of the passivation layer 262 can be compromised, causing it to break down.

The residues resulting from the decomposition of the silane-type passivation layer can be cleaned using similar methods as before. Dilute acidic solutions can effectively remove remaining silicon-containing residues or decomposed organic matter from the surface. Alternatively, etching process using gases such as CF3, C₄F₆, CHF₃, CH₂F₂, CH₃F, NF₃ may be employed to eliminate stubborn residues.

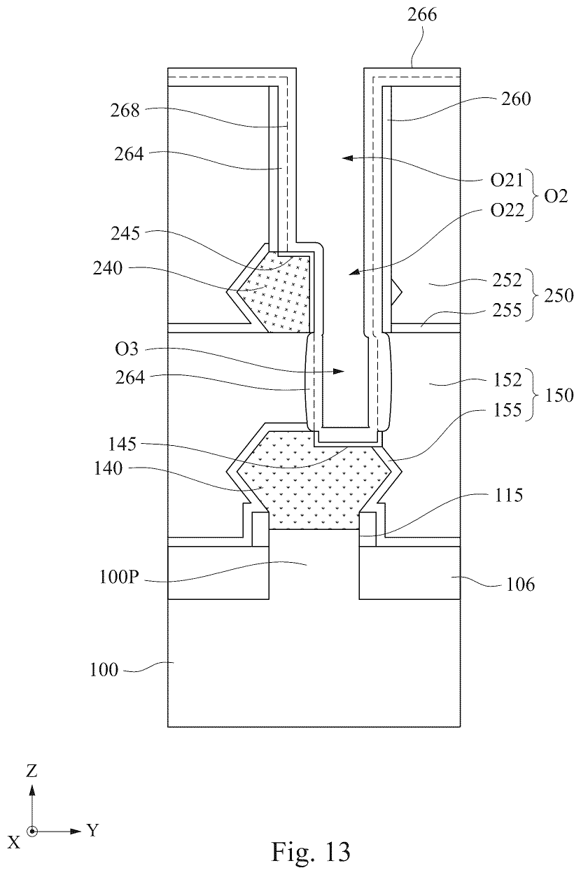

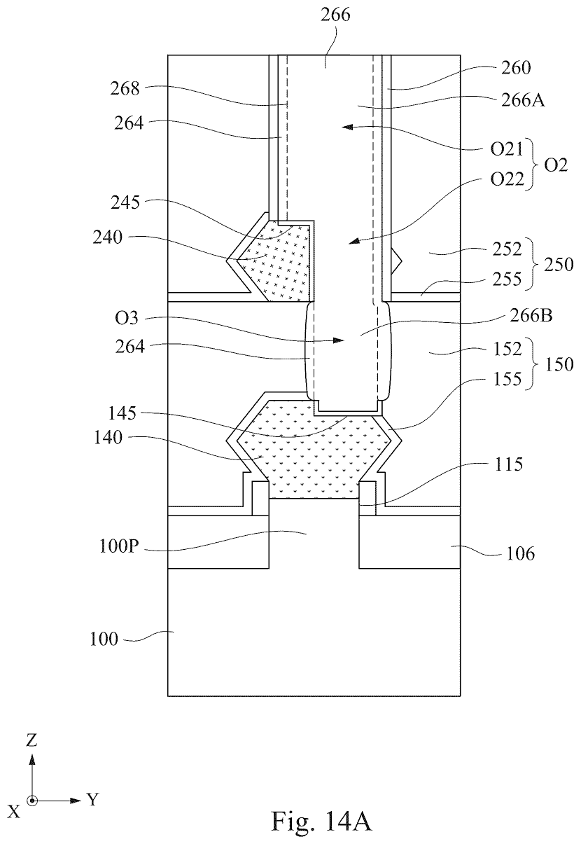

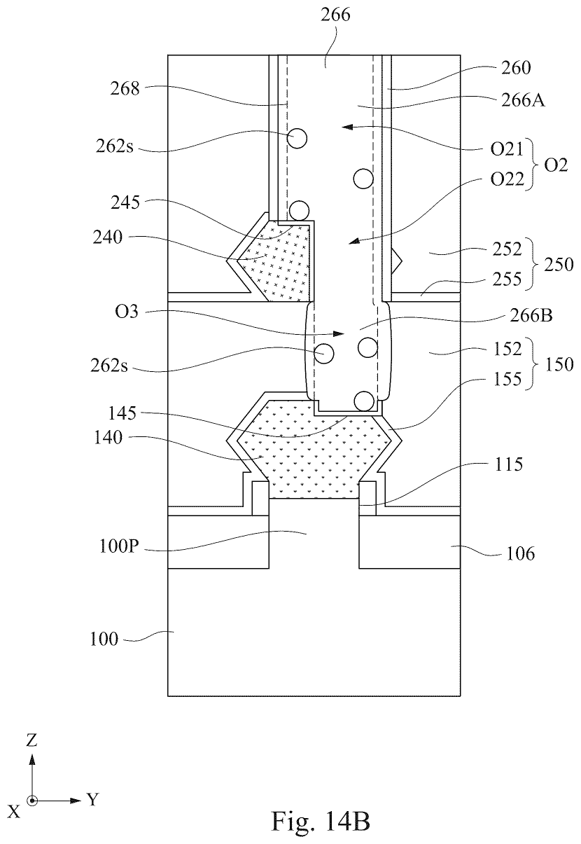

Reference is made to FIGS. 13 and 14A. A contact plug 266 is formed in the openings O2 and O3. When forming the contact plug 266, the conductive material is deposited to fill openings O2 and O3, establishing electrical connections between the first and second epitaxial source/drain regions, and then performing a planarization process (e.g., CMP) until the isolation structure 250 is exposed. In some embodiments, the conductive material may include one or more layers of Co, Ni, W, Ru, Ti, Ta, Cu, Al, TiN, and TaN, combinations thereof, and/or other suitable material. Without the passivation layer 262 (see FIG. 10), the conductive material would deposit more quickly on the exposed metal surfaces (e.g., second silicide layer 245) than on the dielectric surfaces. This disparity occurs because metal surfaces can facilitate faster nucleation and growth of conductive materials due to lower energy barriers and stronger adhesion. The rapid accumulation of conductive material near the second silicide layer 245 could lead to premature closure of opening O2 before opening O3 is adequately filled. This premature bridging effectively blocks the conductive material from filling the opening O3, resulting in the formation of a void within the contact plug 266. Such voids may compromise the electrical integrity of the contact plug, leading to increased resistance or even open circuits, which degrade device performance.

By implementing passivation layer 262, the void can be addressed. The passivation layer as shown in FIG. 10 can prevent the conductive material from depositing on the metal surfaces during the initial stages of deposition. Simultaneously, the seed layer 264 (see FIG. 12) on the dielectric surfaces can promote uniform deposition there, ensuring that the conductive material fills both openings O2 and O3 at similar rates. With deposition rates equalized, the conductive material can fills opening O3 adequately before any bridging occurs in the opening O2. This uniform filling can prevents the formation of voids within the contact plug 266. The elimination of voids can ensure that the contact plug 266 forms a continuous and reliable electrical connection between the source/drain regions, enhancing the overall reliability and performance of the semiconductor device.

Specifically, the contact plug 266 can be in contact with the first silicide layer 145 and the second silicide layer 245, and thus the contact plug 266 can be electrically connected with the first epitaxial source/drain region 140 through the first silicide layer 145, and is electrically connected with the second epitaxial source/drain region 240 through the second silicide layer 245. Accordingly, the contact plug 266 may electrically connects the first epitaxial source/drain region 140 and the overlying second epitaxial source/drain region 240. In some embodiments, the contact plug 266 may include a top portion 266A and a bottom portion 266B extending downward from the bottom surface of the top portion 266A and having a narrower width than the top portion 266A. Here, the top portion 266A may be the portion of the contact plug 266 filled in the opening O2, and the bottom portion 266B may be the portion of the contact plug 266 filled in the opening O3. In some embodiments, the contact plug 266 can also be referred to as source/drain contact.

In some embodiments, the contact plug 266 and the seed layer 264 can be made of the same material and can be formed using similar deposition processes. This approach may result in a continuous and homogeneous layer with no visible interface between the contact plug 266 and the seed layer 264. In some embodiments, the contact plug 266 and the seed layer 264 may be formed of the same material but are deposited in different chambers or at different times during the fabrication process. During the transition between deposition chambers, the wafer may be exposed to the ambient environment, where oxygen is present. This exposure can lead to an oxidation phenomenon on the surface of the seed layer 264. As a result, a thin oxide layer, designated as interface 268, may form between the contact plug 266 and the seed layer 264. In some embodiments, the contact plug 266 and the seed layer 264 can be made of different materials, which in turn results in an interface 268 between the contact plug 266 and the seed layer 264.

Reference is made to FIG. 14B. FIG. 14B illustrates a semiconductor structure corresponding to FIG. 14A in accordance with some embodiments of the present disclosure. While FIG. 14B illustrates the embodiment of semiconductor structure with different structural configurations than the semiconductor structures in FIG. 14A, the present disclosure may repeat reference numerals and/or letters in the various examples. This repetition is for simplicity and clarity and does not dictate a relationship between the various embodiments and/or configurations discussed. As shown in FIG. 14B, the passivation layers 262 can be not completely removed during the cleaning or etching processes, leading to the formation of residual passivation material, designated as residues 262s, within the openings O2 and O3. Consequently, these residues 262s can be found on the surfaces of the first silicide layer 145 and/or the second silicide layer 245. During subsequent processing steps, such as the deposition of the contact plug 266, these residues 262s may migrate to other locations within the structure. As a result, after the formation of the contact plug 266, the residues 262s may also appear on the sidewalls of the contact plug 266. The material composition of residues 262s can be similar to that of the passivation layers 262, including hydrocarbons with resonant electrons or thiol-type passivation agents. In some embodiments, the residue 262s can be interchangeable referred to as a carbon-containing inhibitor.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method to prevent void formation in contact plugs during semiconductor device fabrication by selectively forming passivation layers on metal-containing materials. Specifically, passivation layers (e.g., passivation layers 262 shown in FIG. 10) can be deposited on metal-rich regions (e.g., first and second silicide layers 145 and 245 shown in FIG. 10), while avoiding deposition on non-metal materials (e.g., spacer layer 260 and isolation structures 150 and 250 shown in FIG. 10). By selectively passivating the metal surfaces, the subsequent deposition of a metal-containing layer (e.g., seed layer 264 shown in FIG. 11) occurs only on the dielectric materials. After the seed layer is deposited, the passivation layers are removed to expose the metal surfaces. This can prevent the conductive material from accumulating too quickly on the metal surfaces during contact plug formation. As a result, the contact plug can fill the openings uniformly, effectively preventing the formation of voids that could hinder electrical connectivity. Therefore, this method can enhances the reliability and performance of semiconductor devices by ensuring void-free contact plugs and robust electrical connections between metal-containing regions.

In some embodiments, a method includes patterning an opening extending downwardly through one or more dielectric layers over a substrate to expose a first source/drain region of a first transistor and a second source/drain region of a second transistor overlapping at least a portion of the first source/drain region; forming a first metal silicide layer on the first source/drain region, and a second metal silicide layer on the second source/drain region within the opening; selectively forming a first passivation layer over the first metal silicide layer, and a second passivation layer over the second metal silicide layer; forming a seed layer over the one or more dielectric layers within the opening while leaving the first and second passivation layers uncovered; removing the first and second passivation layers after forming the seed layer; forming a metal layer over the seed layer and the first and second metal silicide layers within the opening to create a source/drain contact. In some embodiments, selectively forming the first and second passivation layers is performed such that the one or more dielectric layers are not covered by first and second passivation layers. In some embodiments, forming the seed layer and selectively forming the first and second metal silicide layers are performed by using a same deposition process. In some embodiments, the first passivation layer is in direct contact with the first metal silicide layer, and the second passivation layer is in direct contact with the second metal silicide layer. In some embodiments, the first and second passivation layers comprise hydrocarbons possessing resonant π-electrons. In some embodiments, the first and second passivation layers comprise aromatic compounds with functional groups capable of forming coordination bonds with the first and second metal silicide layers. In some embodiments, forming the first and second passivation layer comprises: introducing silane-based or thiol-based passivation agents over the substrate to chemically bind to the first and second metal silicide layers. In some embodiments, the first and second passivation layers are monolayers. In some embodiments, removing the first and second passivation layers comprises annealing the substrate at a temperature greater than about 250° C. In some embodiments, a footprint of the opening between the first and second source/drain regions overlaps with footprints of the first and second metal silicide layers.

In some embodiments, a method includes depositing a dielectric layer over a lower epitaxial structure of a lower transistor; forming an upper epitaxial structure of a upper transistor over the dielectric layer; patterning an opening extending downwardly through the upper epitaxial structure and the dielectric layer to expose the lower epitaxial structure; forming an upper metal silicide on the upper epitaxial structure within the opening; selectively forming an inhibitor layer over the upper metal silicide, leaving the dielectric layer uncovered; conformally depositing a metal liner over the dielectric layer within the opening, while keeping the inhibitor layer exposed; removing the inhibitor layer after conformally depositing the metal liner; forming a metal layer over the metal liner and the lower and upper metal silicides within the opening to create a source/drain contact. In some embodiments, the inhibitor layer is a carbon-containing material. In some embodiments, conformally depositing the metal liner is performed such that the inhibitor layer remains uncovered. In some embodiments, the method further includes forming a lower metal silicide on the lower epitaxial structure within the opening, wherein forming the inhibitor layer further comprises forming the inhibitor layer over the lower metal silicide. In some embodiments, patterning the opening is performed such that a lateral dimension of the opening below the upper epitaxial structure is greater than a lateral dimension of the opening in the same level as the upper epitaxial structure.

In some embodiments, a semiconductor structure includes a first transistor, comprising a first source/drain region, a second transistor positioned over the first transistor, a first metal silicide layer, a second metal silicide layer, a contact plug, and a carbon-containing inhibitor residue. The second transistor includes a second source/drain region, and the second source/drain region overlaps at least a portion of the first source/drain region. The first metal silicide layer is formed over a top surface of the first source/drain region. The second metal silicide layer is formed along a sidewall of the second source/drain region. The contact plug extends from the first metal silicide layer to the second metal silicide layer. The carbon-containing inhibitor residue is on a sidewall of the contact plug. In some embodiments, the carbon-containing inhibitor residue comprises aromatic compounds with functional groups capable of forming chemical bonds. In some embodiments, the carbon-containing inhibitor residue is positioned between the second metal silicide layer and the contact plug. In some embodiments, semiconductor structure further includes a seed layer lining the sidewall of the contact plug, wherein the seed layer does not extend over the first and second metal silicide layers. In some embodiments, the carbon-containing inhibitor residue is positioned between the seed layer and the contact plug.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
patterning an opening extending downwardly through one or more dielectric layers over a substrate to expose a first source/drain region of a first transistor and a second source/drain region of a second transistor overlapping at least a portion of the first source/drain region;
forming a first metal silicide layer on the first source/drain region, and a second metal silicide layer on the second source/drain region within the opening;
selectively forming a first passivation layer over the first metal silicide layer, and a second passivation layer over the second metal silicide layer;
forming a seed layer over the one or more dielectric layers within the opening while leaving the first and second passivation layers uncovered;
removing the first and second passivation layers after forming the seed layer; and
forming a metal layer over the seed layer and the first and second metal silicide layers within the opening to create a source/drain contact.

2. The method of claim 1, wherein selectively forming the first and second passivation layers is performed such that the one or more dielectric layers are not covered by first and second passivation layers.

3. The method of claim 1, wherein forming the seed layer and selectively forming the first and second metal silicide layers are performed by using a same deposition process.

4. The method of claim 1, wherein the first passivation layer is in direct contact with the first metal silicide layer, and the second passivation layer is in direct contact with the second metal silicide layer.

5. The method of claim 1, wherein the first and second passivation layers comprise hydrocarbons possessing resonant π-electrons.

6. The method of claim 1, wherein the first and second passivation layers comprise aromatic compounds with functional groups capable of forming coordination bonds with the first and second metal silicide layers.

7. The method of claim 1, wherein forming the first and second passivation layer comprises:
introducing silane-based or thiol-based passivation agents over the substrate to chemically bind to the first and second metal silicide layers.

8. The method of claim 1, wherein the first and second passivation layers are monolayers.

9. The method of claim 1, wherein removing the first and second passivation layers comprises annealing the substrate at a temperature greater than about 250° C.

10. The method of claim 1, wherein a footprint of the opening between the first and second source/drain regions overlaps with footprints of the first and second metal silicide layers.

11. A method, comprising:
depositing a dielectric layer over a lower epitaxial structure of a lower transistor;
forming an upper epitaxial structure of a upper transistor over the dielectric layer;
patterning an opening extending downwardly through the upper epitaxial structure and the dielectric layer to expose the lower epitaxial structure;
forming an upper metal silicide on the upper epitaxial structure within the opening;
selectively forming an inhibitor layer over the upper metal silicide, leaving the dielectric layer uncovered;
conformally depositing a metal liner over the dielectric layer within the opening, while keeping the inhibitor layer exposed;
removing the inhibitor layer after conformally depositing the metal liner; and
forming a metal layer over the metal liner and the lower and upper metal silicides within the opening to create a source/drain contact.

12. The method of claim 11, wherein the inhibitor layer is a carbon-containing material.

13. The method of claim 11, wherein conformally depositing the metal liner is performed such that the inhibitor layer remains uncovered.

14. The method of claim 11, further comprising:
forming a lower metal silicide on the lower epitaxial structure within the opening, wherein forming the inhibitor layer further comprises forming the inhibitor layer over the lower metal silicide.

15. The method of claim 11, wherein patterning the opening is performed such that a lateral dimension of the opening below the upper epitaxial structure is greater than a lateral dimension of the opening in the same level as the upper epitaxial structure.

16. A semiconductor structure, comprising:
a first transistor, comprising a first source/drain region;
a second transistor positioned over the first transistor, the second transistor comprising a second source/drain region, wherein the second source/drain region overlaps at least a portion of the first source/drain region;
a first metal silicide layer formed over a top surface of the first source/drain region;
a second metal silicide layer formed along a sidewall of the second source/drain region;
a contact plug extending from the first metal silicide layer to the second metal silicide layer; and
a carbon-containing inhibitor residue on a sidewall of the contact plug.

17. The semiconductor structure of claim 16, wherein the carbon-containing inhibitor residue comprises aromatic compounds with functional groups capable of forming chemical bonds.

18. The semiconductor structure of claim 16, wherein the carbon-containing inhibitor residue is positioned between the second metal silicide layer and the contact plug.

19. The semiconductor structure of claim 16, further comprising:
a seed layer lining the sidewall of the contact plug, wherein the seed layer does not extend over the first and second metal silicide layers.

20. The semiconductor structure of claim 19, wherein the carbon-containing inhibitor residue is positioned between the seed layer and the contact plug.
